(19) United States
(12) Patent Application Publication
(10) Pub. No.: US 2017/0271417 A1
(43) Pub. Date: Sep. 21, 2017

(54) ORGANIC LIGHT-EMITTING DIODE DOUBLE-SIDED DISPLAY PANEL, ITS MANUFACTURING METHOD AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Wenbin JIA, Beijing (CN); Rui PENG, Beijing (CN); Xinxin WANG, Beijing (CN); Zhijie YE, Beijing (CN); Lei HUANG, Beijing (CN)

(73) Assignees: BOE TECHNOLOGY GROUP CO., LTD., Beijing (CN); HEFEI XINSHENG OPTOELECTRONICS TECHNOLOGY CO., LTD., Anhui (CN)

(21) Appl. No.: 15/259,545

(22) Filed: Sep. 8, 2016

(30) Foreign Application Priority Data
Mar. 18, 2016 (CN) 201610158002.2

(51) Int. Cl. H01L 27/32; H01L 51/56; H01L 51/52; G02F 1/167; G02F 1/1333

(52) U.S. Cl. CPC H01L 27/3232; G02F 1/167; G02F 1/1333; H01L 27/3246; H01L 51/5215; H01L 51/5234; H01L 51/56; G02F 2001/1672; G02F 2001/1676; H01L 2251/5323; H01L 2227/323

(57) ABSTRACT

The present disclosure provides an OLED double-sided display panel, its manufacturing method and a display device. The OLED double-sided display panel includes a base substrate, a plurality of OLEDs formed on the base substrate, and a light control unit arranged at at least one side of the OLEDs. An orthogonal projection of the light control unit onto the base substrate covers an orthogonal projection of each OLED onto the base substrate, and the light control unit is capable of being switched between a transparent state and an opaque state.

### CROSS-REFERENCE TO RELATED APPLICATIONS

This application claims priority to Chinese application No. 201610158002.2, filed Mar. 18, 2016, which is hereby incorporated by reference in its entirety.

### TECHNICAL FIELD

The present disclosure relates to the field of display technology, in particular to an organic light-emitting diode (OLED) double-sided display panel, its manufacturing method, and a display device.

### BACKGROUND

OLED display device has been generally recognized as a next-generation mainstream product and attracted more and more attentions, due to its advantages such as self-luminance, not requiring backlight, high contrast, small thickness, wide viewing angle, rapid response, being adapted to a flexible panel and wide operation temperature range.

As electronic products become more diverse, a double-sided display function has become a main feature for new-generation electronic products, especially for display devices used in public places. Usually, a double-sided display device includes two single-sided display panels attached to each other, e.g., a liquid crystal display (LCD) panel and an OLED display panel, or two OLED display panels.

However, a manufacture process for the double-sided light-emitting panel is complex, and the resultant product has a large thickness as well high production cost. Hence, there is such a trend to manufacture the adjustable OLED double-sided display device using an identical base substrate. In the related art, an anode and a cathode of the OLED double-sided display device are made of transparent metals having a high work function and a low work function respectively. However, it is impossible for the conventional OLED double-sided display device to achieve single-sided display. In addition, during the display, an image has relatively low brightness, and it is impossible to adjust the brightness of the images displayed at the two display panels respectively. These drawbacks greatly limit the commercial application of the OLED double-sided display device.

### SUMMARY

An object of the present disclosure is to provide an OLED double-sided display panel, its manufacturing method and a display device, so as to achieve double-sided display.

In one aspect, the present disclosure provides in some embodiments an OLED double-sided display panel, including a base substrate, a plurality of OLEDs formed on the base substrate, and a light control unit arranged at at least one side of the OLEDs. An orthogonal projection of the light control unit onto the base substrate covers an orthogonal projection of each OLED onto the base substrate, and the light control unit is capable of being switched between a transparent state and an opaque state.

Optionally, the light control unit includes electrophoresis units defined by a plurality of retaining walls. Each of the electrophoresis units includes transparent electrophoretic liquid arranged between the retaining walls, opaque charged particles in the electrophoretic liquid, and electrophoretic electrodes arranged close to the retaining walls. The electrophoretic electrodes are configured to apply an electric field to the charged particles, so as to switch the electrophoresis unit between the opaque state where the charged particles are diffused between the retaining walls and the transparent state where the charged particles are accumulated onto the retaining wall.

Optionally, the opaque charged particles are reflective particles.

Optionally, the OLED double-sided display panel further includes a packaging substrate. A gate electrode, a gate insulation layer, an active layer, a source-drain electrode, and a passivation layer are sequentially arranged at a side of the base substrate close to an organic light-emitting layer. An inorganic packaging layer is arranged at a side of the electrophoresis units close to the organic light-emitting layer, and a planarization layer is arranged at the other side of the electrophoresis units. The packaging substrate is arranged at a side of the planarization layer away from the electrophoresis units.

Optionally, a side of each electrophoresis unit close to the organic light-emitting layer has an area larger than an area of the OLED pixel on the OLED double-sided display panel.

Optionally, the retaining walls are opaque, and the electrophoretic electrodes are transparent.

Optionally, each OLED includes an anode, a cathode, and a light-emitting layer arranged between the anode and the cathode. A pixel definition layer is arranged on the anode, and the anode and the cathode are each made of a transparent material.

In another aspect, the present disclosure provides in some embodiments an OLED double-sided display device including the above-mentioned OLED double-sided display panel.

In yet another aspect, the present disclosure provides in some embodiments a method for manufacturing an OLED double-sided display panel, including steps of forming a plurality of OLEDs on a base substrate, and forming electrophoresis units at at least one side of the OLEDs. The electrophoresis units are capable of being switched between a transparent state and an opaque state.

Optionally, the step of forming the electrophoresis units at at least one side of the OLEDs includes: depositing an inorganic packaging layer at at least one side of the OLEDs; forming retaining walls and electrophoretic electrodes on the inorganic packaging layer, so as to define the electrophoresis unit by the retaining walls; dripping a mixture of electrophoretic liquid and charged particles into the electrophoresis units; and depositing a planarization layer onto the electrophoresis units.

Optionally, subsequent to the step of depositing the planarization layer onto the electrophoresis units, the method further includes attaching a packaging substrate onto the planarization layer in a vacuum environment.

According to the OLED double-sided display panel, its manufacturing method and the display device in the embodiments of the present disclosure, it is able to shield the light at at least one side of the display panel, thereby to achieve the double-sided display. The light control unit includes the electrophoresis units, which may shield the light with the charged particles capable of reflecting the light. In the case of shielding the image not desired to be displayed at a side of the display, the light for displaying an image at the side of the display may be reflected, so as to increase the brightness of the image desired to be displayed at the other side of the display. As a result, it is able to achieve the double-sided display, and meanwhile adjust the brightness of the image to be displayed through the light control unit.

### DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic view showing an OLED double-sided display panel in a single-sided display state according to one embodiment of the present disclosure;

FIG. 2 is a flow chart of a method for manufacturing the OLED double-sided display panel according to one embodiment of the present disclosure;

FIG. 3 is a schematic view showing an OLED according to one embodiment of the present disclosure; and

FIG. 4 is a schematic view showing the OLED double-sided display panel in a double-sided display state according to one embodiment of the present disclosure.

### DETAILED DESCRIPTION

As required, detailed embodiments are disclosed herein. However, it is to be understood that the disclosed embodiments are merely exemplary and that various and alternative forms may be employed. The figures are not necessarily to scale. Some features may be exaggerated or minimized to show details of particular components. Therefore, specific structural and functional details disclosed herein are not to be interpreted as limiting, but merely as a representative basis for teaching one skilled in the art.

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “a” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

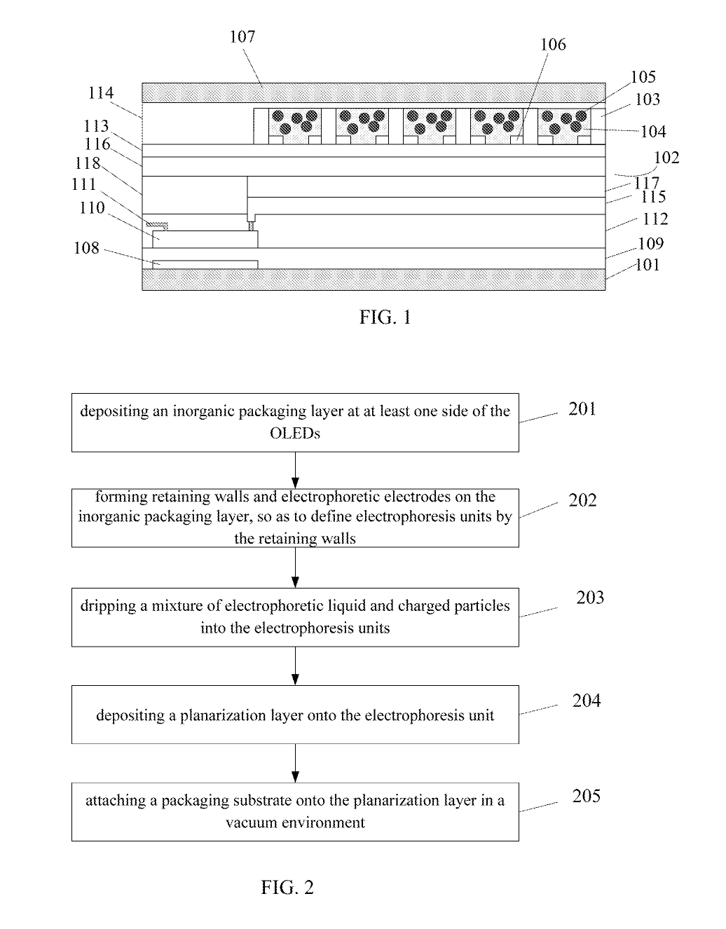

The present disclosure provides in some embodiments an OLED double-sided display panel which, as shown in FIG. 1, includes a base substrate 101, a plurality of OLEDs 102 formed on the base substrate, and a light control unit arranged at at least one side of the OLEDs 102. An orthogonal projection of the light control unit onto the base substrate 101 covers an orthogonal projection of each OLED 102 onto the base substrate 101, and the light control unit is capable of being switched between a transparent state and an opaque state.

According to the OLED double-sided display panel, the light control unit is arranged at at least one side of the OLEDs, so as to switch at least one side of the double-sided display panel between a display state and a non-display state in the case that a power supply is turned on. As a result, it is able to improve the controllability of the display, i.e., to enable a user to select a single-sided display state or a double-sided display state according to the practical need.

In an embodiment of the present disclosure, the light control unit may shield the light at one side of the OLEDs.

In another embodiment of the present disclosure, the light control units may be arranged at both sides of each OLED, so as to control the display at both sides of each OLED.

In some embodiments of the present disclosure, the light control unit includes electrophoresis units defined by a plurality of retaining walls. Each of the electrophoresis units includes transparent electrophoretic liquid arranged between the retaining walls, opaque charged particles in the electrophoretic liquid, and electrophoretic electrodes arranged close to the retaining walls. The electrophoretic electrodes are configured to apply an electric field to the charged particles, so as to switch the electrophoresis unit between the opaque state where the charged particles are diffused between the retaining walls and the transparent state where the charged particles are accumulated onto the retaining wall. An intensity of the electric field between the electrophoretic electrodes may be adjusted by adjusting a voltage difference between the electrophoretic electrodes, so as to enable the light control unit to be switched among the transparent state, the opaque state and a translucent state, thereby to control the brightness of the image at a display side shielded by the light control unit.

In an embodiment of the present disclosure, the opaque charged particles are reflective particles. At this time, in the case that a display side of the display is shielded by the light control unit, the light from the OLED may be reflected by the reflective particles toward the other display side of the display, so as to increase the brightness at the display side not shielded by the light control unit, thereby to control the brightness at both display sides.

In an embodiment of the present disclosure, the light control unit is arranged at a side of each OLED away from the base substrate. Referring again to FIG. 1, the light control unit includes electrophoresis units defined by a plurality of retaining walls 103. Each of the electrophoresis units includes transparent electrophoretic liquid 104 arranged between the retaining walls 103, opaque charged particles 105 in the electrophoretic liquid 104, and electrophoretic electrodes 106 arranged close to the retaining walls 103. The electrophoretic electrodes 106 are configured to apply an electric field to the charged particles 105, so as to switch the electrophoresis unit between the opaque state where the charged particles 105 are diffused between the retaining walls 103 and the transparent state where the charged particles 105 are accumulated onto the retaining wall 103. Further, the charged particles 105 are reflective particles. Each electrophoresis unit includes two electrophoretic electrodes 106 arranged close to the retaining walls 103 at edges of the electrophoresis unit. One of the retaining wall 103 and the electrophoretic electrode 106 is opaque, and the other one of the retaining wall 103 and the electrophoretic electrode 106 is transparent. For example, the retaining wall 103 may be transparent and the electrophoretic electrode 106 may be opaque, or the retaining wall 103 may be opaque and the electrophoretic electrode 106 may be transparent. In this way, it is able to prevent the light from passing through the light control unit in the case that the light control unit is in the opaque state, and prevent the light from being shielded in the case that the light control unit in the transparent state.

The charged particles 105 may be positive or negative particles, and there is a voltage difference between the two electrophoretic electrodes 106. In the case that the charged particles 105 are positive particles, the charged particles 105 may be accumulated onto the electrophoretic electrode 106 as a negative electrode of the electric field after the electrophoretic electrodes 106 are energized. In the case that the charged particles 105 are negative particles, the charged particles 105 may be accumulated onto the electrophoretic electrode 106 as a positive electrode of the electric field after the electrophoretic electrodes 106 are energized. A distribution density of the charged particles 105 in the electrophoresis unit may be adjusted by controlling an intensity of the electric field between the electrophoretic electrodes 106, so as to switch the light control unit among the transparent state, the opaque state and any translucent state (e.g., a 50% transparent state), thereby to control the brightness at both display sides.

In the embodiments of the present disclosure, voltage signals applied to the electrophoretic electrodes may be adjusted, so as to adjust the distribution of the charged particles and control the light from a side of the OLED pixels close to the electrophoresis units, thereby to achieve the single-sided display or double-sided display, or adjust the brightness at both display sides. The resultant OLED double-sided display panel has a simple structure and may be controlled more flexibly, so it may be commercially applied to various scenarios in a public place.

For example, the OLED double-sided display panel is provided, with one display side facing an indoor environment and the other display side facing an outdoor environment. In the day time, the brightness for the display side facing the outdoor environment needs to be high due to the strong ambient light, while the brightness for the display side facing the indoor environment may be low due to the weak ambient light. At this time, the light control unit may be provided for the display side facing the outdoor environment, and certain voltages may be applied to the electrophoretic electrodes, so as to adjust the distribution of the charged particles in the electrophoresis units, thereby to reduce the brightness at the display side facing the indoor environment and increase the brightness at the display side facing the outdoor environment. Thus, both outdoor users and indoor users may see the image being displayed clearly in the day time.

In another embodiment of the present disclosure, the light control units may be provided for both display sides of the OLED double-sided display panel facing the indoor environment and the outdoor environment respectively, so as to adjust the brightness for both display sides in accordance with the ambient light.

In some embodiments of the present disclosure, referring again to FIG. 1, the OLED double-sided display panel further includes a packaging substrate 107. A gate electrode 108, a gate insulation layer 109, an active layer 110, a source-drain electrode 111, and a passivation layer 112 are sequentially arranged at a side of the base substrate 101 close to an organic light-emitting layer 117. An inorganic packaging layer 113 is arranged at a side of the electrophoresis units close to the organic light-emitting layer 117, and a planarization layer 114 is arranged at the other side of the electrophoresis units. The packaging substrate 107 is arranged at a side of the planarization layer 114 away from the electrophoresis units. Each OLED includes an anode 115, a cathode 116, and a light-emitting layer 117 arranged between the anode and the cathode. A pixel definition layer 118 is arranged on the anode 115, and both the anode 115 and the cathode 116 are made of a transparent material.

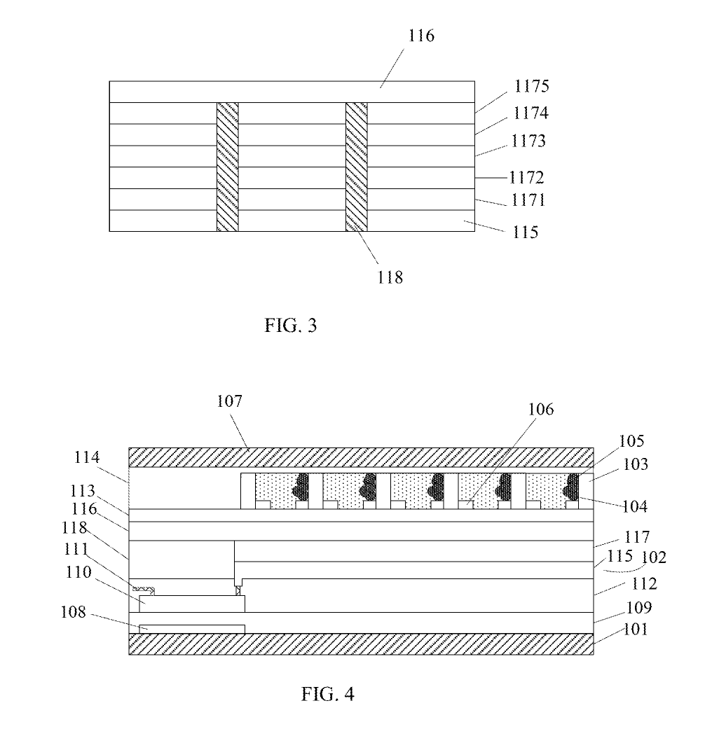

In an embodiment of the present disclosure, as shown in FIG. 3, the OLED includes the anode 115, the pixel definition layer 118, a hole injection layer 1171, a hole transport layer 1172, a red-green-blue (RGB) organic light-emitting unit 1173, an electron transport layer 1174, an electron injection layer 1175, and the cathode 116. To be specific, the anode 115 and the cathode 116 are both transparent.

In some embodiments of the present disclosure, a side of each electrophoresis unit close to the organic light-emitting layer has an area larger than an area of the OLED pixel on the OLED double-sided display panel. The electrophoresis unit mainly functions as to shield the light at the display side, so the precision of the electrophoresis unit may not be so highly required, so as to simplify the manufacture thereof.

In some embodiments of the present disclosure, the retaining walls are opaque, and the electrophoretic electrodes are transparent. In the case that the charged particles cover the electrophoretic electrodes, it is able to shield the light passing through the transparent electrophoretic electrodes. In addition, in the display state, the display may not be adversely affected by the transparent electrophoretic electrodes. Hence, optionally, the electrophoretic electrodes may be transparent. In any cases, the charged particles may not cover the retaining wall, so the retaining wall may optionally be transparent or opaque.

In the actual application, in the case that no voltage is applied to the two electrophoretic electrodes 106 of each electrophoresis unit or there is no voltage difference between the two electrophoretic electrodes 106, the charged particles 105 may be diffused in the electrophoresis unit. At this time, the charged particles 105 may shield the light of the electrophoretic electrodes, so that the user cannot be view any image at a side of the electrophoresis units away from the OLED 102. In the case that the charged particles 105 are reflective particles, the user may view the display image at a side close to the base substrate 101, and at this time the brightness of the image is higher than that in the double-sided display state. In the case that there is a voltage difference between the two electrophoretic electrodes 106 of respective electrophoresis units, an electric field may be generated between the electrophoretic liquids, and at this time, the charged particles 105 may move toward the oppositely charged electrode, until all the charged particles 105 are accumulated thereto. As shown in FIG. 4, the display panel is in the double-sided display state, and the images may be viewed from both the position close to the packaging substrate 107 and the position close to the base substrate 101.

The present disclosure further provides in some embodiments an OLED double-sided display device including the above-mentioned OLED double-sided display panel.

The present disclosure further provides in some embodiments a method for manufacturing the OLED double-sided display panel, including steps of forming a plurality of OLEDs on a base substrate, and forming electrophoresis units at at least one side of the OLEDs. The electrophoresis units are capable of being switched between a transparent state and an opaque state.

In some embodiments of the present disclosure, as shown in FIG. 2, the step of forming the electrophoresis units at at least one side of the OLEDs includes: Step 201 of depositing the inorganic packaging layer at at least one side of the OLEDs; Step 202 of forming the retaining walls and the electrophoretic electrodes on the inorganic packaging layer, so as to define the electrophoresis unit by the retaining walls; Step 203 of dripping a mixture of the electrophoretic liquid and the charged particles into the electrophoresis units; and Step 204 of depositing the planarization layer onto the electrophoresis units.

In some embodiments of the present disclosure, subsequent to the step of depositing the planarization layer onto the electrophoresis units, the method further includes Step 205 of attaching the packaging substrate onto the planarization layer in a vacuum environment.

In an embodiment of the present disclosure, the OLED double-sided display panel includes the base substrate and the packaging substrate. A gate electrode, a gate insulation layer, an active layer, a source-drain electrode, and a passivation layer are sequentially arranged at a side of the base substrate close to an organic light-emitting layer. An inorganic packaging layer is arranged at a side of the electrophoresis units close to the organic light-emitting layer, and a planarization layer is arranged at the other side of the electrophoresis units. The packaging substrate is arranged at a side of the planarization layer away from the electrophoresis units. The OLED includes a base, an anode, a pixel definition layer, a hole injection layer, a hole transport layer, a RGB organic light-emitting unit, an electron transport layer, and an electron injection layer. The method for manufacturing the OLED double-sided display panel includes: forming the gate electrode of the driving transistor, the gate insulation layer, the active layer, the source-drain electrode of the driving transistor, the passivation layer, the transparent anode of the OLED and the pixel definition layer on the base substrate through exposing, developing and etching processes; depositing the hole injection layer, the hole transport layer, the RGB organic light-emitting layer, the electron transport layer, the electron injection layer and the transparent cathode (which is made of indium tin oxide) onto the anode by vacuum evaporation using a fine metal mask (FMM); depositing the inorganic packing layer on the cathode through chemical vapor deposition (CVD); forming the electrophoretic electrodes and the retaining walls on the inorganic packaging layer through exposing and etching processes, so as to define the electrophoresis units by the retaining walls; dripping a mixture of the transparent electrophoretic liquid and the reflective charged particles into each of the electrophoresis units; depositing the transparent planarization layer on all of the electrophoresis units; and attaching the packaging substrate to the base substrate through the transparent planarization layer in a vacuum environment, so as to form the double-sided display panel.

According to the OLED double-sided display panel, its manufacturing method and the display device in the embodiments of the present disclosure, it is able to shield the light at at least one side of the display panel, thereby to achieve the double-sided display. The light control unit includes the electrophoresis units, which may shield the light with the charged particles capable of reflecting the light. Therefore, in the case of shielding the image not desired to be displayed at a side of the display, the light for displaying an image at the side of the display may be reflected, so as to increase the brightness of the image desired to be displayed at the other side of the display. As a result, it is able to achieve the double-sided display, and meanwhile adjust the brightness of the image to be displayed through the light control unit. In addition, the OLED double-sided display may achieve both the single-sided display and the double-sided display as well as brightness adjusting.

It should be appreciated that, the above-mentioned embodiments are for illustrative purposes only, but shall not be used to limit the scope of the present disclosure. In the case of no conflict, the embodiments and the features therein may be combined in any way.

The above are merely the preferred embodiments of the present disclosure. Obviously, a person skilled in the art may make further modifications and improvements without departing from the spirit of the present disclosure, and these modifications and improvements shall also fall within the scope of the present disclosure.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. An organic light-emitting diode (OLED) double-sided display panel, comprising a base substrate, a plurality of OLEDs formed on the base substrate, and a light control unit arranged at at least one side of the OLEDs, wherein an orthogonal projection of the light control unit onto the base substrate covers an orthogonal projection of each OLED onto the base substrate, and the light control unit is capable of being switched between a transparent state and an opaque state.

2. The OLED double-sided display panel according to claim 1, wherein the light control unit comprises electrophoresis units defined by a plurality of retaining walls;
each of the electrophoresis units comprises transparent electrophoretic liquid arranged between the retaining walls, opaque charged particles in the electrophoretic liquid, and electrophoretic electrodes arranged close to the retaining walls; and
the electrophoretic electrodes are configured to apply an electric field to the charged particles, so as to switch the electrophoresis unit between the opaque state where the charged particles are diffused between the retaining walls and the transparent state where the charged particles are accumulated onto the retaining wall.

3. The OLED double-sided display panel according to claim 2, wherein the opaque charged particles are reflective particles.

4. The OLED double-sided display panel according to claim 3, further comprising a packaging substrate, wherein a gate electrode, a gate insulation layer, an active layer, a source-drain electrode, and a passivation layer are sequentially arranged at a side of the base substrate close to an organic light-emitting layer, an inorganic packaging layer is arranged at a side of the electrophoresis units close to the organic light-emitting layer, a planarization layer is arranged at the other side of the electrophoresis units, and the packaging substrate is arranged at a side of the planarization layer away from the electrophoresis units.

5. The OLED double-sided display panel according to claim 2, wherein a side of each electrophoresis unit close to the organic light-emitting layer has an area larger than an area of an OLED pixel on the OLED double-sided display panel.

6. The OLED double-sided display panel according to claim 3, wherein a side of each electrophoresis unit close to the organic light-emitting layer has an area larger than an area of an OLED pixel on the OLED double-sided display panel.

7. The OLED double-sided display panel according to claim 1, wherein a side of each electrophoresis unit close to the organic light-emitting layer has an area larger than an area of an OLED pixel on the OLED double-sided display panel.

8. The OLED double-sided display panel according to claim 2, wherein the retaining walls are opaque, and the electrophoretic electrodes are transparent.

9. The OLED double-sided display panel according to claim 3, wherein the retaining walls are opaque, and the electrophoretic electrodes are transparent.

10. The OLED double-sided display panel according to claim 1, wherein each of the OLEDs comprises an anode, a cathode, and a light-emitting layer arranged between the anode and the cathode, a pixel definition layer is arranged on the anode, and the anode and the cathode are each made of a transparent material.

11. The OLED double-sided display panel according to claim 2, wherein each of the OLEDs comprises an anode, a cathode, and a light-emitting layer arranged between the anode and the cathode, a pixel definition layer is arranged on the anode, and the anode and the cathode are each made of a transparent material.

12. An OLED double-sided display device comprising the OLED double-sided display panel according to claim 1.

13. The OLED double-sided display device according to claim 12, wherein the light control unit comprises electrophoresis units defined by a plurality of retaining walls;
each of the electrophoresis units comprises transparent electrophoretic liquid arranged between the retaining walls, opaque charged particles in the electrophoretic liquid, and electrophoretic electrodes arranged close to the retaining walls; and
the electrophoretic electrodes are configured to apply an electric field to the charged particles, so as to switch the electrophoresis unit between the opaque state where the charged particles are diffused between the retaining walls and the transparent state where the charged particles are accumulated onto the retaining wall.

14. The OLED double-sided display device according to claim 13, wherein the opaque charged particles are reflective particles.

15. The OLED double-sided display device according to claim 14, wherein the OLED double-sided display panel further comprises a packaging substrate, wherein a gate electrode, a gate insulation layer, an active layer, a source-drain electrode, and a passivation layer are sequentially arranged at a side of the base substrate close to an organic light-emitting layer, an inorganic packaging layer is arranged at a side of the electrophoresis units close to the organic light-emitting layer, a planarization layer is arranged at the other side of the electrophoresis units, and the packaging substrate is arranged at a side of the planarization layer away from the electrophoresis units.

16. The OLED double-sided display device according to claim 13, wherein a side of each electrophoresis unit close to the organic light-emitting layer has an area larger than an area of an OLED pixel on the OLED double-sided display panel.

17. The OLED double-sided display device according to claim 13, wherein the retaining walls are opaque, and the electrophoretic electrodes are transparent.

18. A method for manufacturing an OLED double-sided display panel, comprising steps of:
forming a plurality of OLEDs on a base substrate; and
forming electrophoresis units at at least one side of the OLEDs,
wherein the electrophoresis units are capable of being switched between a transparent state and an opaque state.

19. The method according to claim 18, wherein the step of forming the electrophoresis units at at least one side of the OLEDs comprises:
depositing an inorganic packaging layer at at least one side of the OLEDs;
forming retaining walls and electrophoretic electrodes on the inorganic packaging layer, so as to define the electrophoresis units by the retaining walls;
dripping a mixture of electrophoretic liquid and charged particles into the electrophoresis units; and
depositing a planarization layer onto the electrophoresis units.

20. The method according to claim 19, wherein subsequent to the step of depositing the planarization layer onto the electrophoresis units, the method further comprises attaching a packaging substrate onto the planarization layer in a vacuum environment.
